(19) United States
(12) Patent Application Publication
(10) Pub. No.: US 2025/0072121 A1
(43) Pub. Date: Feb. 27, 2025

(54) SEMICONDUCTOR DEVICE

(71) Applicant: Socionext Inc., Kanagawa (JP)

(72) Inventor: Isaya SOBUE, Yokohama (JP)

(21) Appl. No.: 18/946,496

(22) Filed: Nov. 13, 2024

Related U.S. Application Data
(63) Continuation of application No. PCT/JP2022/020835, filed on May 19, 2022.

(51) Int. Cl. H01L 27/02

(52) U.S. Cl. CPC H01L 27/0255

(57) ABSTRACT

A first impurity region and a second impurity region, having first and second types of conductivity, respectively, are formed on a substrate, spaced apart from each other in a first direction, in contact with a third impurity region a fourth impurity region, which are also provided on the substrate with the second and first types of conductivity, respectively. Interconnects that extend in a second direction, which is different from the first direction, are formed in the substrate, on the side of the third impurity region facing the fourth impurity region side, and on the side of the fourth impurity region facing the third impurity region. By this means, when multiple diodes are arranged next to each other, it is still possible to prevent or substantially prevent the semiconductor device's chip size from increasing.

### CROSS-REFERENCE TO RELATED APPLICATION

The present application is a continuation application filed under 35 U.S.C. 111 (a) claiming the benefit under 35 U.S.C. 120 and 365 (c) of PCT International Application No. PCT/JP2022/020835, filed on May 19, 2022, and designating the U.S. The entire contents of PCT International Application No. PCT/JP2022/020835 are incorporated herein by reference.

### BACKGROUND OF THE INVENTION

### 1. Field of the Invention

The present invention relates to a semiconductor device.

### 2. Description of the Related Art

An electro-static discharge (ESD) protection that is provided in a semiconductor device to protect the inner circuitry of the semiconductor device from ESD has long been known. For example, a conductor buried in a trench may be used as interconnects for diodes formed in an ESD protection circuit, or interconnects for a bi-directional diode arranged between varying power-supply domains. An interconnect that is buried for use as a power-supply interconnect or a ground interconnect may be referred to as a “buried power rail” (BPR).

### CITATION LIST

### Patent Document

[Patent Document 1] International Publication No. WO2020/235082
[Patent Document 2] International Publication No. WO2020/235084
[Patent Document 3] International Publication No. WO2017/212644

### SUMMARY OF THE INVENTION

### Technical Problem

When multiple diodes are placed next to each other in an ESD protection circuit, a bi-directional diode, and so forth, these diodes are spaced apart, in order not to activate the parasitic bipolar transistors formed between neighboring diodes. However, when the diode layout region increases in area (size), the semiconductor device's chip size also increases.

The present invention has been made in view of the foregoing, and aims to prevent or substantially prevent the chip size of a semiconductor device from increasing when multiple diodes are arranged next to each other.

### Solution to Problem

According to an example of the present invention, a semiconductor device includes: a substrate; a first impurity region and a second impurity region formed on the substrate, the first and second impurity regions having first and second types of conductivity, respectively, and spaced apart in a first direction in plan view; a third impurity region formed in contact with the first impurity region on the substrate and having the second type of conductivity; a fourth impurity region formed in contact with the second impurity region on the substrate and having the first type of conductivity; a first interconnect formed in the substrate, on a side of the third impurity region facing the fourth impurity region in plan view, the first interconnect extending in a second direction that is different from the first direction; and a second interconnect formed in the substrate, on a side of the fourth impurity region facing the third impurity region in plan view, the second interconnect extending in the second direction.

### Advantageous Effects of Invention

According to the technique disclosed herein, it is possible to prevent or substantially prevent the chip size of a semiconductor device from increasing when multiple diodes are arranged next to each other.

### BRIEF DESCRIPTION OF DRAWINGS

FIG. 1 is a circuit diagram that illustrates examples of principal parts in a semiconductor device according to a first embodiment;

FIG. 2 is a plan view that illustrates an example layout of the region in which the diodes of FIG. 1 are formed;

FIG. 3 is a cross-sectional view taken along line X1-X2 in FIG. 2;

FIG. 4 is a cross-sectional view taken along line Y1-Y2 in FIG. 2;

FIG. 5 is a cross-sectional view that illustrates an example in which the transistors of FIG. 2 are formed with FinFET transistors;

FIG. 6 is a plan view that illustrates another example structure of the diode regions of FIG. 2;

FIG. 7 is a cross-sectional view taken along line X1-X2 in FIG. 6;

FIG. 8 is a plan view that illustrates yet another example structure of the diode regions of FIG. 2;

FIG. 9 is a cross-sectional view taken along line X1-X2 in FIG. 8;

FIG. 10 is a circuit diagram that illustrates examples of principal parts in a semiconductor device according to a second embodiment;

FIG. 11 is a plan view that illustrates an example layout of the bi-directional diode region of FIG. 10;

FIG. 12 is a circuit diagram that illustrates examples of principal parts in a semiconductor device according to a third embodiment; and

FIG. 13 is a plan view that illustrates an example layout of the transistors and diodes in FIG. 12.

### DETAILED DESCRIPTION OF THE PREFERRED EMBODIMENTS

Embodiments of the present invention will be described below with reference to the accompanying drawings. In the following description, a reference code that indicates a signal will also be used as reference code that indicates a signal interconnect or a signal terminal. Likewise, a reference code that indicates a voltage will also be used as a reference code that indicates the voltage interconnect or the voltage terminal where the voltage is supplied.

### First Embodiment

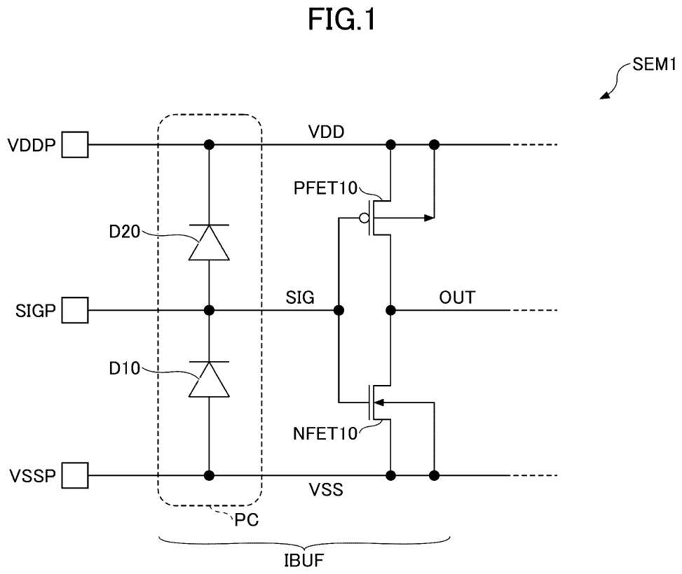

FIG. 1 illustrates examples of principal parts in a semiconductor device according to a first embodiment. For example, a semiconductor device SEM1 illustrated in FIG. 1 may be a “system on chip” (SoC), or may be a single central processing unit (CPU), graphics processing unit (GPU), digital signal processor (DSP), field-programmable gate array (FPGA), memory, or the like. FIG. 1 illustrates an example of an input buffer circuit IBUF that receives a signal SIG in the semiconductor device SEM1.

The input buffer circuit IBUF includes: an ESD protection circuit PC including diodes D10 and D20; a p-type field effect transistor PFET10; and an n-type field effect transistor NFET10. “P-type” is an example of the first type of conductivity or a second type of conductivity, and “n-type” is an example of the second type of conductivity or the first type of conductivity.

The diode D10 has its anode connected to a ground interconnect VSS and cathode connected to a signal interconnect SIG. The diode D20 has its anode connected to the signal interconnect SIG and cathode connected to a power-supply interconnect VDD. The ground interconnect VSS is connected to a ground pad VSSP, and the power-supply interconnect VDD is connected to a power-supply pad VDDP. The signal interconnect SIG is connected to a signal pad SIGP.

Field effect transistors PFET10 and NFET10 constitute an inverter that inverts the logic of a signal SIG and outputs the resulting signal. In the following description, a p-type field effect transistor PFET will be also referred to as a “transistor PFET,” and an n-type field effect transistor NFET will be also referred to as a “transistor NFET.” For example, the transistors PFET10 and NFET10 are nanosheet transistors, but this is by no means a limitation.

The gates of the transistors PFET10 and NFET10 are connected to the signal interconnect SIG and receive a signal SIG that is supplied to the signal pad SIGP. The drains of the transistors PFET10 and NFET10 are connected to an output node OUT of an input buffer circuit IBUF. The source and backgate of the transistor PFET10 are connected to the power-supply interconnect VDD. The source and backgate of the transistor NFET10 are connected to the ground interconnect VSS. The power-supply interconnect VDD is an example of a first power-supply interconnect or a second power-supply interconnect, and the ground interconnect VSS is an example of a second power-supply interconnect or a first power-supply interconnect.

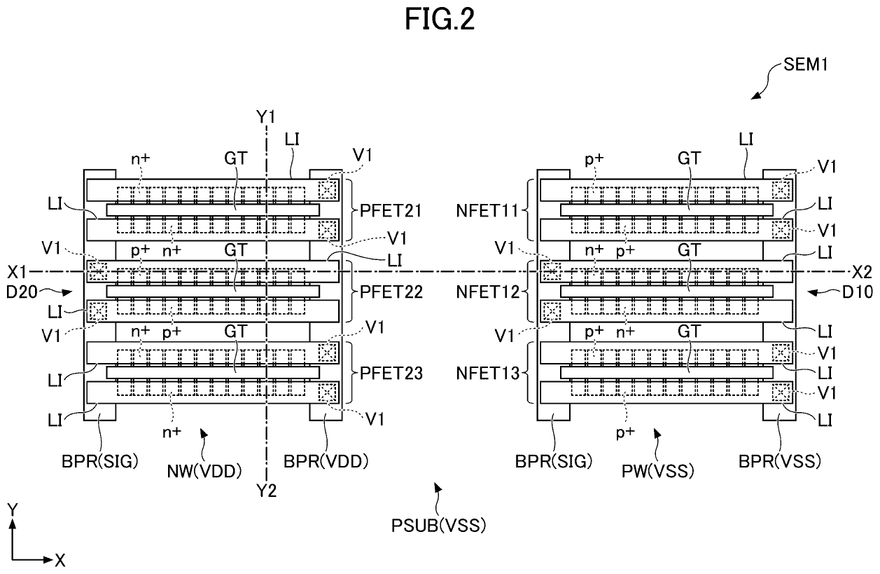

FIG. 2 shows, in plan view, an example layout of a region in which the diodes D20 and D10 of FIG. 1 are formed. The diodes D20 and D10 are arranged next to each other in the X direction in FIG. 2. In the region in which the diode D20 is formed, transistors PFET (PFET21, PFET22, and PFET23) are arranged in the Y direction in FIG. 2. In the region in which the diode D10 is formed, transistors NFET (NFET11, NFET12, and NFET13) are arranged in the Y direction in FIG. 2. The X direction is an example of a first direction. The Y direction is an example of a second direction that intersects the X direction.

For example, the transistors PFET and NFET are nanosheet transistors. Each transistor PFET or NFET has: a gate electrode GT that extends in the X direction; diffusion regions (p+ (p-type) or n+ (n-type) regions) that are arranged on both sides of the gate electrode GT relative to the Y direction; and local interconnects LI that are connected to the diffusion regions. In the following description, the region in which the diode D20 is formed will be also referred to as “diode region D20,” and the region in which the diode D10 is formed will be also referred to as “diode region D10.”

The p+ diffusion regions of the transistors PFET22, NFET11, and NFET13 correspond to the source regions and drain regions of the transistors PFET22, NFET11, and NFET13. The n+ diffusion regions of the transistors PFET21, PFET23, and NFET12 correspond to source drain the regions and regions of the transistors PFET21, PFET23, and NFET12.

In the diode region D20, the p+ diffusion regions of the transistor PFET22 are connected to a buried power rail BPR (SIG) via local interconnects LI and vias V1. The buried power rail BPR (SIG) is connected to the signal interconnect SIG. Note that, in FIG. 2, the vias V1 are represented by dashed quadrilaterals, with the symbol “X” placed thereon. The transistor PFET22 is an example of the first transistor.

The n+ diffusion regions of the transistors PFET21 and PFET23 are connected to a buried power rail BPR (VDD) via local interconnects LI and vias V1. The buried power rail BPR (VDD) is connected to the power-supply interconnect VDD. The n+ diffusion regions of the transistors PFET21 and PFET23 are in contact with an n-type well region NW (VDD) on the surface of a p-type semiconductor substrate PSUB (VSS).

By this means, the power-supply voltage VDD of the buried power rail BPR (VDD) can be supplied to the well region NW (VDD) via the n+ diffusion regions of the transistors PFET21 and PFET23. Then, the p+ diffusion regions and the well region NW (VDD) of the transistor PFET22 can form a pn junction and constitute the diode D20 of FIG. 1.

The buried power rail BPR (SIG) in the diode region D20 is formed on the opposite side from the diode region D10 in the well region NW (VDD). On the other hand, the buried power rail BPR (VDD) is formed on the same side as the diode region D10 in the well region NW (VDD). That is, in the diode region D20, the buried power rail BPR (SIG) and BPR (VDD) are formed on both sides of the transistors PFET21 to PFET23 in the X direction. In the diode region D20, the buried power rail BPR (SIG) is an example of a third interconnect, and the buried power rail BPR (VDD) is an example of the first interconnect.

Note that the buried power rail BPR (SIG) may be formed on the same side as the diode region D10, and the buried power rail BPR (VDD) may be formed on the opposite side from the diode region D10. In this case, the vias V1 of the transistor PFET22 may be formed on the same side as the diode region D10, and the vias V1 of the transistors PFET21 and PFET23 may be formed on the opposite side from the diode region D10. Furthermore, only one of the buried power rail BPR (VDD) and the buried power rail BPR (SIG) may be formed on the same side as the diode region D10. Then, instead of the other one of the buried power rail BPR (VDD) and the buried power rail BPR (SIG), the other one of the power-supply interconnect VDD and the signal interconnect SIG may be formed in a wiring layer situated above the transistors PFET, and be connected with interconnects LI.

In the diode region D10, the n+ diffusion regions of the transistor NFET12 are connected to a buried power rail BPR (SIG) via local interconnects LI and vias V1. The buried power rail BPR (SIG) is connected to the signal interconnect SIG. The transistor NFET12 is an example of a second transistor.

The p+ diffusion regions of the transistors NFET11 and NFET13 are connected to a buried power rail BPR (VSS) via local interconnects LI and vias V1. The buried power rail BPR (VSS) is connected to the ground interconnect VSS. The p+ diffusion regions of the transistors NFET11 and NFET13 are in contact with a p-type well region PW (VSS) on the surface of the semiconductor substrate PSUB (VSS).

By this means, the ground voltage VSS of the buried power rail BPR (VSS) can be supplied to the well region PW (VSS) via the p+ diffusion regions of the transistors NFET11 and NFET13. Then, the well region PW (VSS) and the n+ diffusion regions of the transistor NFET12 can form a pn junction and constitute the diode D10 of FIG. 1.

The buried power rail BPR (SIG) in the diode region D10 is formed on the same side as the diode region D20 in the well region PW (VSS). The buried power rail BPR (VSS) is formed on the opposite side from the diode region D20 in the well region PW (VSS). That is, in the diode region D10, the buried power rail BPR (SIG) and BPR (VSS) are formed on both sides of the transistors NFET11 to NFET13 in the X direction. In the diode region D10, the buried power rail BPR (SIG) is an example of a second interconnect, and the buried power rail BPR (VSS) is an example of a fourth interconnect.

Note that, in the diode region D10, the buried power rail BPR (SIG) may be formed on the opposite side from the diode region D20, and the buried power rail BPR (VSS) may be formed on the same side as the diode region D20. In this case, the vias V1 of the transistor NFET12 may be formed on the opposite side from the diode region D20, and the vias V1 of the transistors NFET11 and NFET13 may be formed on the same side as the diode region D20. Furthermore, only one of the buried power rail BPR (VSS) and the buried power rail BPR (SIG) may be formed on the same side as the diode region D20. Then, instead of the other one of the buried power rail BPR (VSS) and the buried power rail BPR (SIG), the other one of the ground interconnect VSS and the signal interconnect SIG may be formed in a wiring layer situated above the transistors NFET, and be connected with interconnects LI.

A semiconductor layer such as a diffusion region or a well region is not formed between the diode regions D20 and D10, so this part of the semiconductor substrate PSUB (VSS) remains unfabricated. Also, the well region NW (VDD) of the diode region D20 and the well region PW (VSS) of the diode region D10 are separated by respective buried power rails BPR (VDD) and BPR (SIG).

Therefore, the leakage current component between the well regions NW (VDD) and PW (VSS) can be reduced, so that it is possible to prevent or substantially prevent a parasitic bipolar transistor from being activated therebetween. Alternatively, it is possible to prevent or substantially prevent a parasitic bipolar transistor from being formed between the diode regions D20 and D10. By this means, the gap between the diode regions D20 and D10 can be narrowed compared to the case in which the buried power rails BPR (VDD) and BPR (SIG) are not formed, so that the chip size of the semiconductor device SEM1 can be made smaller.

Note that the diode regions D20 and D10 may be arranged alternately and repeatedly in the X direction. Buried power rails BPR are formed on both sides of the diode region D20 in the X direction and on both sides of the diode region D10 in the X direction. Therefore, even when diode regions D20 and D10 are arranged alternately and repeatedly in the X direction, it is possible to prevent or substantially prevent a parasitic bipolar transistor from being activated, or from being formed, between diode regions D20 and D10 that are arranged next to each other. By this means, the gap between multiple sets of diodes D20 and D10 can be narrowed, so that the chip size of the semiconductor device SEM1 can be made even smaller.

Note that, in the diode region D20, four or more transistors PFET may be arranged side by side in the Y direction. Similarly, in the diode region D10, four or more transistors NFET may be arranged side by side in the Y direction. In this case, p+ diffusion regions and n+ diffusion regions are formed alternately in each diode region D20 and D10.

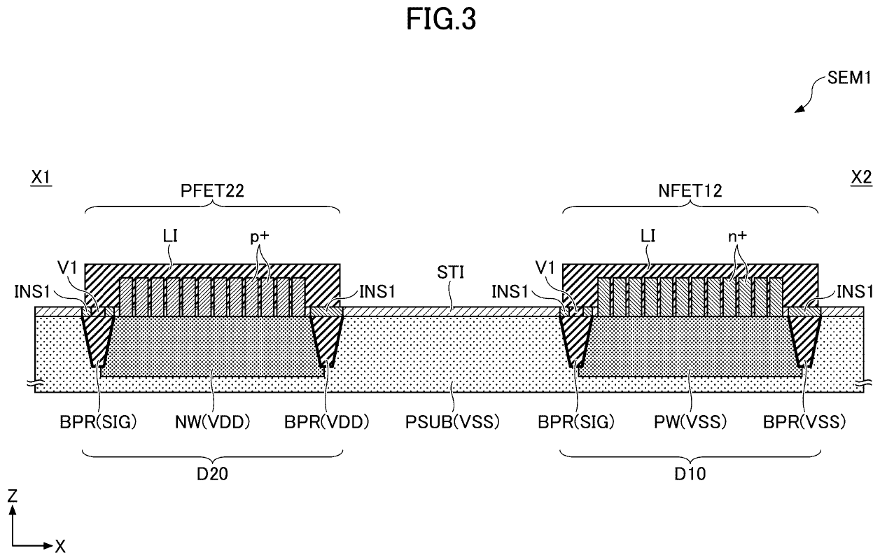

FIG. 3 shows a cross section taken along line X1-X2 in FIG. 2. Nanosheet-type transistors PFET22 and NFET12 are formed on a semiconductor substrate PSUB (VSS). On the surface of the semiconductor substrate PSUB (VSS), a shallow trench isolation (STI) layer is formed as an insulating film. The thick solid lines surrounding the buried power rails BPR (SIG), BPR (VDD), and BPR (VSS) are insulating films. The local interconnects LI, buried power rails BPR, and vias V1 are formed by using metal materials such as ruthenium, tungsten, molybdenum, copper, and so forth, but this is by no means a limitation.

As described above with reference to FIG. 2, in the diode region D20, the p+ diffusion regions of the transistor PFET22 are connected to a buried power rail BPR (SIG) via local interconnects LI and vias V1. An insulating film INS1 made of silicon nitride or silicon carbide is formed between the local interconnects LI and the buried power rail BPR (SIG), except for the region where the vias V1 are formed. Then, the p+ diffusion regions and the well region NW (VDD) of the transistor PFET22 can form a pn junction and constitute the diode D20.

In the diode region D10, the n+ diffusion regions of the transistor NFET12 are connected to a buried power rail BPR (SIG) formed in the semiconductor substrate PSUB (VSS) via local interconnects LI and vias V1. An insulating film INS1 is formed between the local interconnects LI and the buried power rail BPR (SIG). Then, the p-type well region PW (VSS) and the n+ diffusion regions of the transistor NFET12 can form a pn junction and constitute the diode D10.

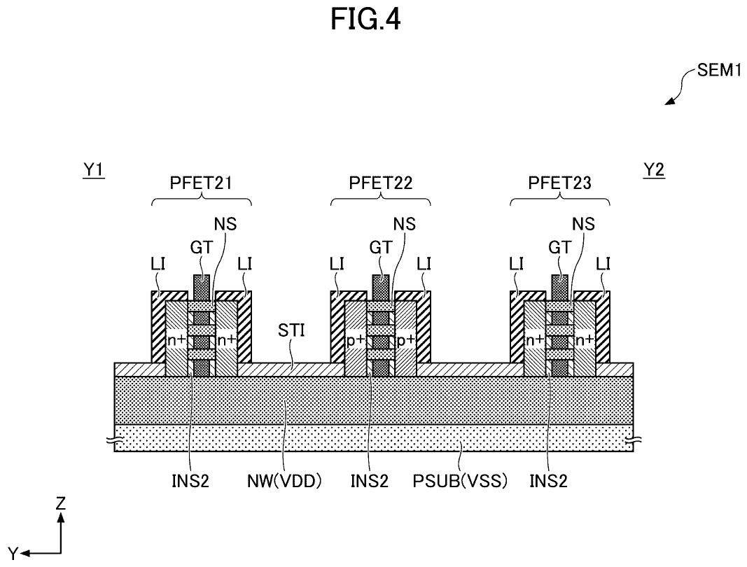

FIG. 4 shows a cross section taken along line Y1-Y2 in FIG. 2. In the transistor PFET22, the p+ diffusion regions arranged on both sides of the gate GT in the Y direction are connected with each other via multiple nanosheets NS. The local interconnects LI of the transistor PFET22 are connected to the well region NW (VDD) via the p+ diffusion regions.

In each of the transistors PFET21 and PFET23, the n+ diffusion regions arranged on both sides of the gate GT in the Y direction are connected with each other via multiple nanosheets NS. The local interconnects LI of the transistors PFET21 and PFET23 are connected to the well region NW (VDD) via the n+ diffusion regions.

In the transistors PFET21 to PFET23, multiple nanosheets NS are formed at intervals in the Z direction, which is the thickness direction of the semiconductor substrate PSUB. Then, an insulating film INS2 is formed between the gate electrode GT and the n+ diffusion regions, and between the gate electrode GT and the p+ diffusion regions. By this means, in the transistor PFET22, the gate electrode GT and the p+ diffusion regions are insulated by the insulating film INS2, and, in the transistors PFET21 and PFET23, the gate electrode GT and the n+ diffusion regions are insulated by the insulating film INS2. Also, a gate insulating film (not shown) is formed between the gate electrode GT and nanosheets NS.

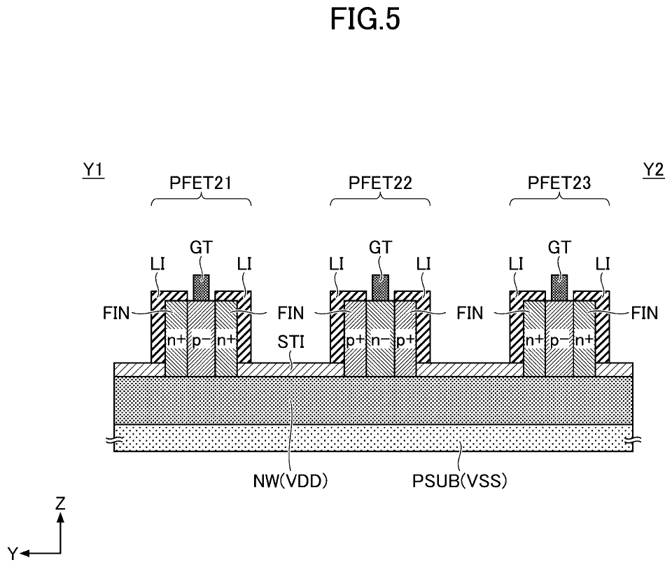

FIG. 5 illustrates an example in which the transistors PFET21 to PFET23 of FIG. 2 are formed with FinFET transistors. In the transistors PFET21 and PFET23, a p-type diffusion region, p−, is formed between a pair of n+ diffusion regions (fins) that form the source region and the drain region, instead of the nanosheets NS of FIG. 4. In the transistor PFET22, an n-type diffusion region, n−, is formed between a pair of p+ diffusion regions (fins) that form the source region and the drain region, instead of the nanosheet NS in FIG. 4. Also, a gate insulating film (not shown) is formed between the gate electrode GT and the fins.

The reference code “p−” indicates that the impurity concentration is lower than where the reference code “p+” is shown. The reference code “n-” indicates that the impurity concentration is lower than where reference code “n+” is shown. Note that the transistors NFET11 to NFET23 in FIG. 2 have the same or substantially the same structure as in FIG. 5 even when they are formed with FinFET transistors. In this case, the n+ diffusion regions and p+ diffusion regions in FIG. 5 are switched, and the n-diffusion regions and p− diffusion regions in FIG. 5 are switched.

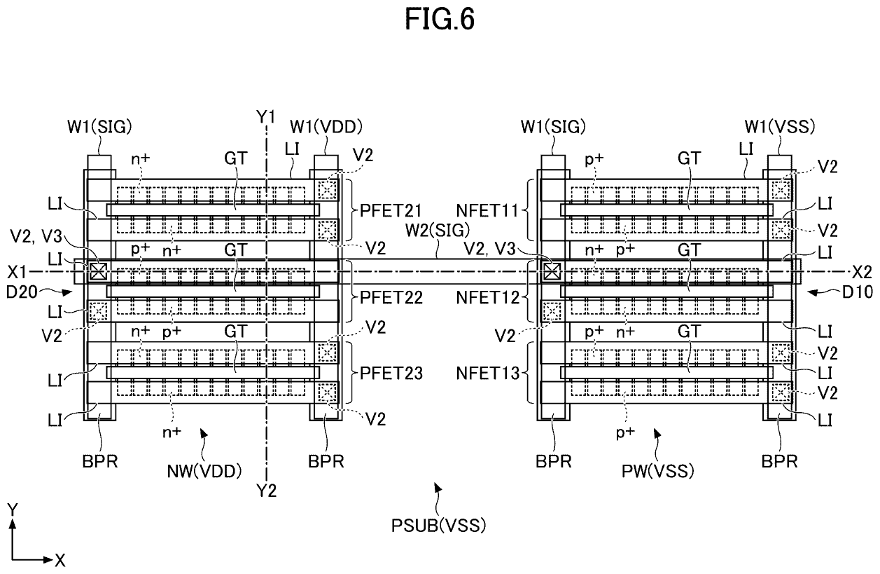

FIG. 6 illustrates an example of another structure of the diode regions D20 and D10 of FIG. 2 in plan view. FIG. 6 is the same or substantially the same as the planar structure of FIG. 2, except that the signal interconnects SIG, power-supply interconnect VDD, and ground interconnect VSS of the diode regions D20 and D10 are connected to interconnects formed in a wiring layer situated above the transistors PFET and NFET, respectively. The vias V1 illustrated in FIG. 2 are not formed in FIG. 6. Therefore, each buried power rail BPR is set to a floating state.

In the diode region D20, the local interconnect LI connected to the p+ diffusion regions of the transistor PFET22 are connected to a signal SIG interconnect W1 (SIG) via vias V2. Also, the local interconnects LI connected to the n+ diffusion regions of the transistors PFET21 and PFET23 are connected to an interconnect W1 (VDD) for power-supply voltage VDD via the vias V2. For example, the interconnect W1 (SIG) and the interconnect W1 (VDD) are formed to extend in the Y direction.

In the diode region D10, the local interconnects LI connected to the n+ diffusion regions of the transistor NFET12 are connected to a signal SIG interconnect W1 (SIG) via the vias V2. Also, the local interconnect LI connected to the p+ diffusion regions transistors NFET11 and NFET13 are connected to the interconnect W1 (VSS) for ground voltage VSS via the vias V2. For example, the interconnect W1 (SIG) and the interconnect W1 (VSS) are formed to extend in the Y direction.

Furthermore, the interconnect W1 (SIG) of the diode region D20 and the interconnect W1 (SIG) of the diode region D10 are connected with each other via an interconnect W2 (SIG) that is formed above the interconnect W1 (SIG) via vias V3. For example, the interconnect W2 (SIG) is formed to extend in the X direction. In FIG. 6, the vias V2 and V3 are represented by dashed quadrilaterals, with the symbol “X” placed thereon.

For example, the interconnects W1 (SIG), W1 (VDD), W1 (VSS), and W2 (SIG) are formed using the same or substantially the same metal material as the local interconnects LI. Note that the formation of the interconnects W2 (SIG), which connect between the interconnects W1 (SIG) of the diode regions D20 and D10, may be omitted.

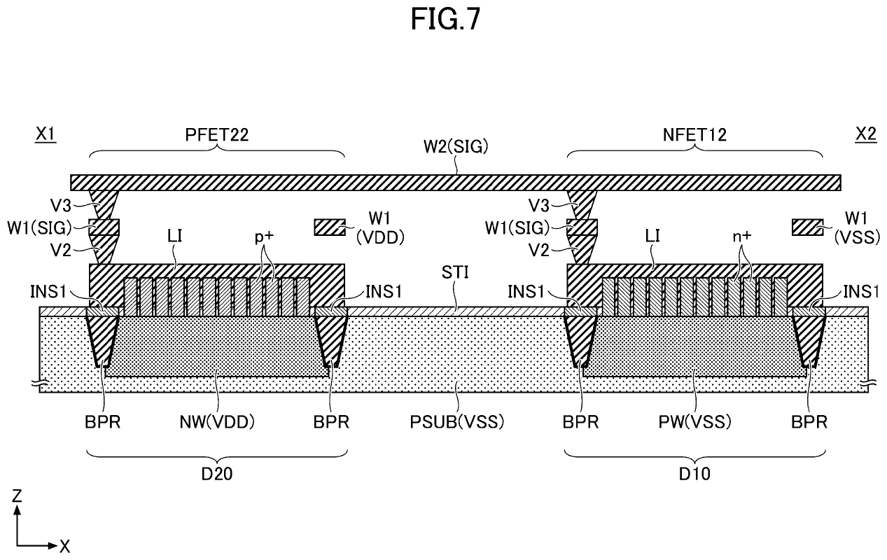

FIG. 7 shows a cross section taken along line X1-X2 in FIG. 6. FIG. 7 is the same or substantially the same as FIG. 3, except that the local interconnects LI of the transistors PFET22 and NFET12 are connected to interconnects W1 (SIG) and W2 (SIG) of a higher layer, and the buried power rails BPR are set to a floating state.

Also in the structures illustrated in FIG. 6 and FIG. 7, as in the structures illustrated in FIG. 2 to FIG. 4, the well regions NW (VDD) and PW (VSS) are separated by buried power rails BPR. Therefore, it is possible to prevent or substantially prevent a parasitic bipolar transistor from being activated between the well regions NW (VDD) and PW (VSS). Alternatively, it is possible to prevent or substantially prevent a parasitic bipolar transistor from being formed between the diode regions D20 and D10. By this means, the gap between diode regions D20 and D10 can be narrowed, so that the chip size of the semiconductor device SEM1 can be made smaller.

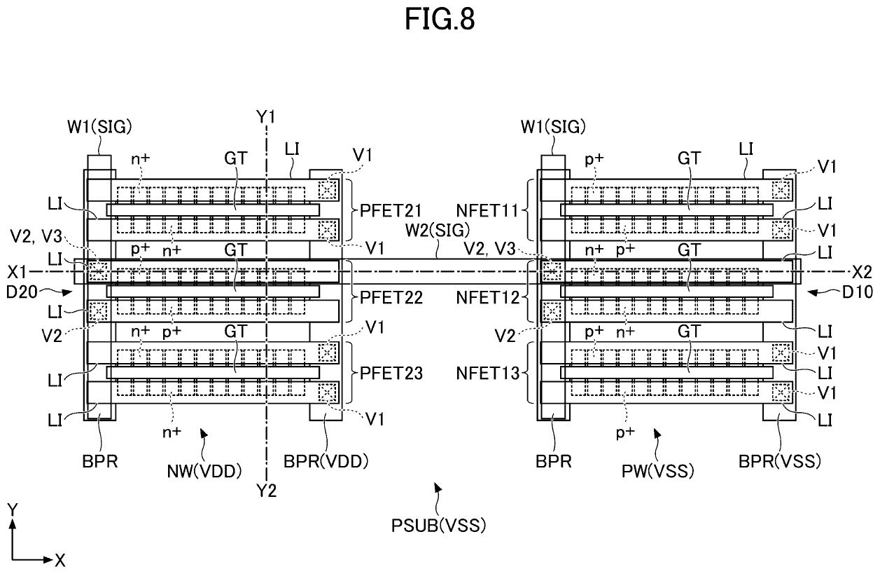

FIG. 8 shows another example structure of the diode regions D20 and D10 of FIG. 2 in plan view. Parts that are the same or substantially the same as in FIG. 6 will not be described in detail below. In FIG. 8, in the diode region D20, as in FIG. 2, the power-supply voltage VDD of the n+ diffusion regions of the transistors PFET21 and PFET23 is supplied from a buried power rail BPR (VDD) via vias V1 and local interconnects LI.

Also, in the diode region D10, as in FIG. 2, the ground voltage VSS of the p+ diffusion regions of the transistors NFET11 and NFET13 is supplied from a buried power rail BPR (VSS) via vias V1 and local interconnects LI. Therefore, in FIG. 8, the interconnects W1 (VDD) and W1 (VSS) illustrated in FIG. 6 are not formed. The rest of the structure of the diode regions D20 and D10 is the same or substantially the same as in FIG. 2.

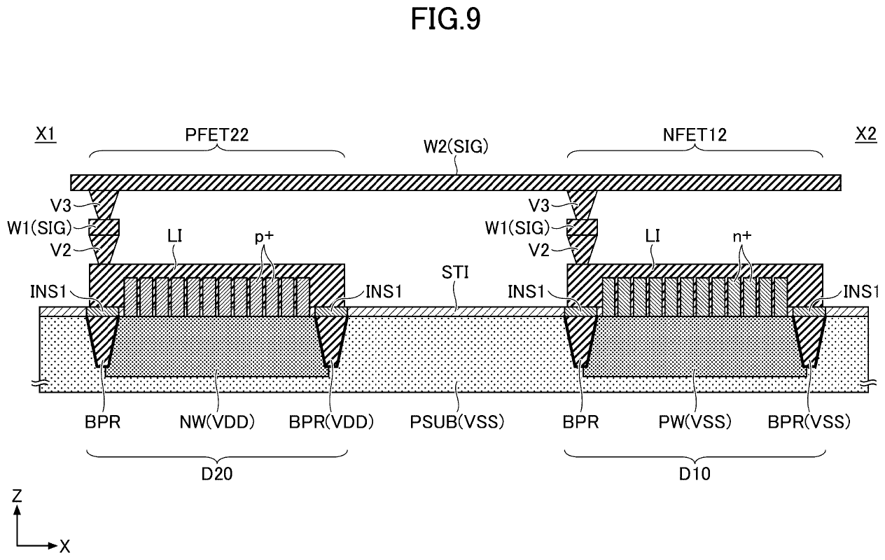

FIG. 9 shows a cross section taken along line X1-X2 in FIG. 8. Parts that are the same or substantially the same as in FIG. 7 will not be described in detail. FIG. 9 shows the buried power rails BPR (VDD) and BPR (VSS) of FIG. 3, and is the same or substantially the same as FIG. 7, except that the interconnects W1 (VDD) and W1 (VSS) of FIG. 7 are not formed. Note that the buried power rail BPR (VDD) may be formed on the opposite side from the diode region D10, and the buried power rail BPR (VSS) may be formed on the same side as the diode region D20.

According to the structures illustrated in FIG. 8 and FIG. 9, it is also possible, as with the structures illustrated in FIG. 2 to FIG. 4, and FIG. 6 to FIG. 7, to prevent a parasitic bipolar transistor from being activated between the well regions NW (VDD) and PW (VSS). Alternatively, it is possible to prevent or substantially prevent a parasitic bipolar transistor from being formed between diode regions D20 and D10. By this means, the gap between diode regions D20 and D10 can be narrowed, so that the chip size of the semiconductor device SEM1 can be made smaller.

As described above, according to this embodiment, semiconductor layers such as diffusion regions or well regions are not formed between the diode regions D20 and D10 that are formed next to each other in the protection circuit PC for ESD. The well region NW (VDD) of the diode region D20 and the well region PW (VSS) of the diode region D10 are separated by a buried power rail BPR.

Therefore, the leakage current component between the well regions NW (VDD) and PW (VSS) can be reduced, so that it is possible to prevent or substantially prevent a parasitic bipolar transistor from being activated therebetween. Alternatively, it is possible to prevent or substantially prevent a parasitic bipolar transistor from being formed between the diode regions D20 and D10. Consequently, the diode regions D20 and D10 need not be provided with guard rings.

By this means, the gap between diode regions D20 and D10 can be narrowed, so that the chip size of the semiconductor device SEM1 can be made smaller. In other words, when multiple diodes D20 and D10 are arranged next to each other, it is possible to prevent or substantially prevent the area of the layout region of the diodes D20 and D10 from increasing, and prevent or substantially prevent the chip size of the semiconductor device SEM1 from increasing.

Referring to FIG. 2, by connecting the n+diffusion regions of the transistors PFET21 and PFET23 formed in the Y direction of the transistor PFET22 to a buried power rail BPR (VDD), power-supply voltage VDD can be applied to the well region NW (VDD) f the diode region D20. By connecting the p+ diffusion regions of the transistors NFET11 and NFET13 formed in the Y direction of the transistor NFET12 to a buried power rail BPR (VSS), ground voltage VSS can be supplied to the well region PW (VSS) of the diode region D10.

Therefore, even when diode regions D20 and D10 are arranged alternately and repeatedly in the X direction, it is possible to prevent or substantially prevent a parasitic bipolar transistor from being activated, or from being formed, between diode regions D20 and D10 that are arranged next to each other. By this means, the gap between multiple sets of diodes D20 and D10 can be narrowed, so that the chip size of the semiconductor device SEM1 can be made even smaller.

### Second Embodiment

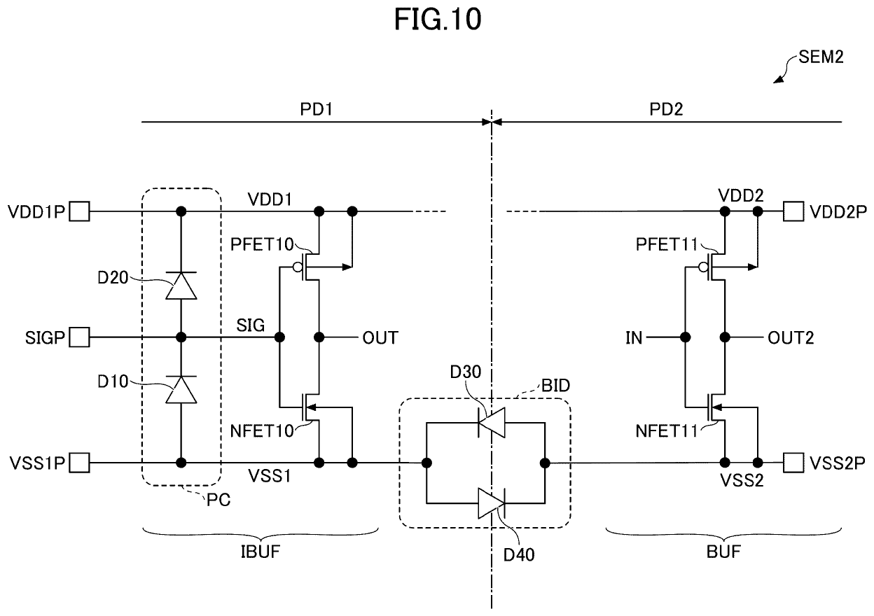

FIG. 10 illustrates examples of principal parts in a semiconductor device according to a second embodiment. Parts that are the same or substantially the same as in FIG. 1 will be assigned the same reference codes, and their detailed explanation will be omitted. The semiconductor device SEM2 illustrated in FIG. 10 may be an SoC, a single CPU, a GPU, a DSP, an FPGA, a memory, and so forth.

FIG. 10 shows, in the semiconductor device SEM2, an input buffer circuit IBUF and a buffer circuit BUF of respective power-supply domains; and bi-directional diode BID including diodes D30 and D40 connected with ground interconnects VSS1 and VSS2. In the following description, the region in which the bi-directional diode BID is formed will be also referred to as a “bi-directional diode region BID.”

The input buffer circuit IBUF is formed in a power-supply domain PD1, and the buffer circuit BUF is formed in a power-supply domain PD2 . . . . The input buffer circuit IBUF has the same structure as in FIG. 1, except that the input buffer circuit IBUF is connected to a power-supply interconnect VDD1 and a ground interconnect VSS1 instead of to the power-supply interconnect VDD and the ground interconnect VSS. The power-supply interconnect VDD1 is connected to a power-supply pad VDD1P, and the ground interconnect VSS1 is connected to a ground pad VSS1P. The power-supply domain PD1 is an example of a first power-supply domain, and the power-supply domain PD2 is an example of a second power-supply domain.

The buffer circuit BUF has an inverter including field effect transistors PFET11 and NFET11 connected in series between a power-supply interconnect VDD2 and a ground interconnect VSS2. The gates of the transistors PFET11 and NFET11 are connected to an input node IN. The drains of the transistors PFET11 and NFET11 are connected to an output node OUT2 of the buffer circuit BUF.

The source and backgate of the transistor PFET11 are connected to the power-supply interconnect VDD2. The source and backgate of the transistor NFET11 are connected to the ground interconnect VSS2. The power-supply interconnect VDD2 is connected to a power-supply pad VDD2P, and the ground interconnect VSS2 is connected to a ground pad VSS2P.

The diode D30 of the bi-directional diode BID has its anode connected to the ground interconnect VSS2 and cathode connected to the ground interconnect VSS1. The diode D40 of the bi-directional diode BID has its anode connected to the ground interconnect VSS1 and cathode connected to the ground interconnect VSS2.

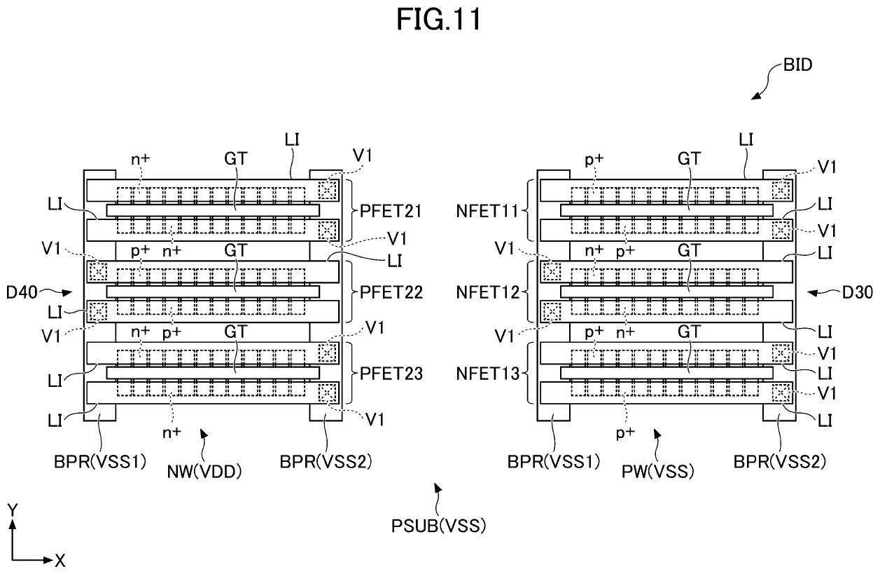

FIG. 11 illustrates an example layout of the bi-directional diode region BID illustrated in FIG. 10 in plan view. Parts that are the same or substantially the same as in FIG. 2 will be assigned the same reference codes, and will not be described in detail. In the following description, the region in which the diode D30 is formed will be also referred to as “diode region D30.” The region in which the diode D40 is formed will be also referred to as “diode region D40.”

In the diode region D40, the buried power rails BPR arranged on both sides of the diode region D40 in the X direction are connected to the ground interconnect VSS1 and ground interconnect VSS2, respectively, instead of to the signal interconnect SIG and power-supply interconnect VDD of FIG. 2. The rest of the configuration and structure of the diode D40 are the same or substantially the same, respectively, as those of the diode region D20 of FIG. 2.

In the diode region D30, the buried power rails BPR arranged on both sides of the diode region D30 in the X direction are connected to the ground interconnect VSS1 and ground interconnect VSS2, respectively, instead of to the signal interconnect SIG and ground interconnect VSS of FIG. 2. The rest of the configuration and structure of the diode D30 are the same or substantially the same as those of the diode region D10 of FIG. 2.

For example, although the transistors PFET21 to PFET23 and NFET11 to NFET13 are nanosheet transistors, they may be formed by FinFET transistors illustrated in FIG. 5. The diode regions D40 and D30 may be arranged alternately and repeatedly in the X direction. Also, the structure illustrated in FIG. 6 may be applied instead of the structure illustrated in FIG. 11.

As described above, this embodiment can also bring about the same or substantially the same effects and advantages as those of the first embodiment described above. For example, in the bi-directional diode BID above, the well region NW (VDD) of the diode region D40 and the well region PW (VSS) of the diode region D30, which are formed next to each other, are separated by buried power rails BPR (VSS1) and BPR (VSS2). By this means, it is possible to prevent or substantially prevent a parasitic bipolar transistor from being activated, or prevent a parasitic bipolar transistor from being formed, between the diode regions D40 and D30. As a result of this, for example, the gap between the diode regions D40 and D30 formed at boundaries between multiple power-supply domains PD1 and PD2 can be narrowed, so that the chip size of the semiconductor device SEM2 can be made smaller.

### Third Embodiment

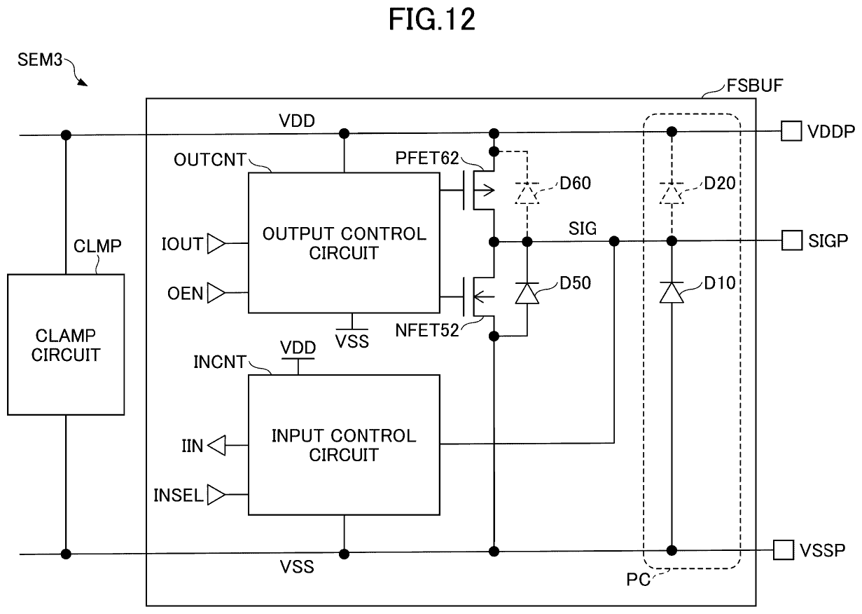

FIG. 12 illustrates examples of principal parts in a semiconductor device according to a third embodiment. Parts that are the same or substantially the same as in FIG. 1 will be assigned the same reference codes and will not be described in detail. The semiconductor device SEM3 illustrated in FIG. 12 may be an SoC, a single CPU, a GPU, a DSP, an FPGA, a memory, or the like. FIG. 12 shows a fail-safe IO buffer FSBUF and an ESD clamp circuit CLMP in the semiconductor device SEM3.

The fail-safe IO buffer FSBUF includes an output control circuit OUTCNT, an input control circuit INCNT, a p-type field effect transistor PFET 62, an n-type field effect transistor NFET52, and diodes D50, D60, D10, and D20. The diodes D50 and D60 are parasitic diodes that are formed when the transistors PFET 62 and NFET52 are formed. The diodes D10 and D20 are formed as an ESD protection circuit PC, as in FIG. 1.

The fail-safe IO buffer FSBUF is an IO buffer that allows input of a signal from a signal pad SIGP when the power-supply voltage VDD is not supplied from a power-supply pad VDDP. When the power-supply voltage VDD is not supplied from the power-supply pad VDDP, the power-supply interconnect VDD changes to a ground voltage VSS. In this state, an existing technique may be used to exert control such that, when the voltage is applied to the signal pad SIGP, no current flows in the diodes D20 and D60 shown by broken lines, in order to prevent a through current from flowing from the signal pad SIGP to the power-supply interconnect VDD of ground voltage VSS.

The output control circuit OUTCNT is in output mode when an output enable signal OEN shows a valid level. The output control circuit OUTCNT outputs a logic level that is opposite to the logic level of an inner output signal IOUT, to the gates of the transistors PFET 62 and NFET52. The output control circuit OUTCNT enters output inhibit mode when the output enable signal OEN is at an invalid level, outputting a high level to the gate of the transistor PFET 62 and a low level to the gate of the transistor NFET52. By this means, the output control circuit OUTCNT operates as a tri-state buffer.

The input control circuit INCNT enters input mode when the output enable signal OEN is at a high level. When the input selection signal INSEL shows a valid level during input mode, the input control circuit INCNT outputs the signal SIG, received by the signal pad SIGP, as an inner input signal IIN. When the input selection signal INSEL is at an invalid level during the input mode, the input control circuit INCNT fixes the inner input signal IIN to a low level, regardless of the logic level of the signal SIG received by the signal pad SIGP.

When a positive ESD voltage is applied from the signal pad SIGP with reference to the power-supply voltage VDD, a current flows from the signal pad SIGP to the power-supply interconnect VDD via the ground interconnect VSS and clamp circuit CLMP due to parasitic bipolar action of the transistor NFET52. Also, the clamp circuit CLMP allows current to flow from the power-supply interconnect VDD to the ground interconnect VSS when a negative ESD voltage is applied from the signal pad SIGP with respect to the power-supply voltage VDD. The current flowing into the ground interconnect VSS flows to the signal pad SIGP via the diodes D50 and D10.

By this means, the fail-safe IO buffer FSBUF is protected against ESD discharge. Note that the operation that takes place when a positive ESD voltage is applied from the signal pad SIGP with reference to the ground voltage VSS is the same or substantially the same as the operation when a positive ESD voltage is applied with reference to the power-supply voltage VDD. The operation that takes place when a negative ESD voltage is applied from the signal pad SIGP with reference to the ground voltage VSS is the same or substantially the same as the operation that takes place when a negative ESD voltage is applied with respect to the power-supply voltage VDD.

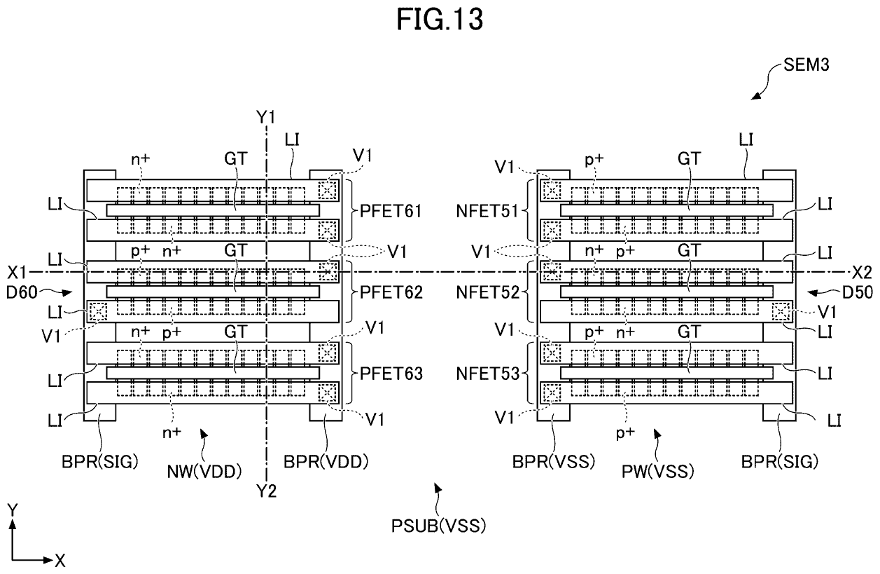

FIG. 13 illustrates an example layout of the transistors PFET 62 and NFET52 and the diodes D60 and D50 of FIG. 12 in plan view. Parts that are the same or substantially the same as in FIG. 2 will be assigned the same reference codes, and will not be described in detail. The cross-sectional structure taken along line X1-X2 in FIG. 13 is the same or substantially the same as that of FIG. 3, except that the vias V are formed at different positions. The structure of the cross section along Y1-Y2 path in FIG. 13 is the same or substantially the same as that of FIG. 4. In the following description, the region in which the diode D60 is formed will be also referred to as “diode region D60,” and the region in which the diode D50 is formed will be also referred to as “diode region D50.”

The diode region D60 includes transistors PFET 61, PFET 62, and PFET 63. The n+ diffusion regions of the transistors PFET 61 and PFET 63 are connected to a power-supply interconnect VDD via local interconnects LI, vias V1, and a buried power rail BPR, which is the same or substantially the same as the n+ diffusion regions of the transistors PFET21 and PFET23 in FIG. 2.

In the transistor PFET 62, the p+ diffusion region arranged on one side in the Y direction relative to the gate electrode GT is connected to the signal interconnect SIG via a local interconnect LI, a via V1, and a buried power rail BPR (SIG). Likewise, in the transistor PFET 62, the p+ diffusion region arranged on the other side of the Y direction relative to the gate electrode GT is connected to the power-supply interconnect VDD via a local interconnect LI, a via V1 and a buried power rail BPR (VDD). By this means, a transistor PFET 62 that functions as a circuit can be formed. The transistor PFET 62 is an example of a first transistor, and the gate electrode of the transistor PFET 62 is an example of a first gate electrode.

The diode region D50 includes transistors NFET51, NFET52, and NFET53. The p+ diffusion regions of the transistors NFET51 and NFET53 are connected to the ground interconnect VSS via local interconnects LI, vias V1 and a buried power rail BPR (VSS), which is the same or substantially the same as the p+ diffusion regions of the transistors NFET11 and NFET13 in FIG. 2.

In the transistor NFET52, the n+ diffusion region arranged on one side in the Y direction relative to the gate electrode GT is connected to the signal interconnect SIG via a local interconnect LI, a via V1, and a buried power rail BPR (SIG). Likewise, in the transistor NFET52, the n+ diffusion region arranged on the other side in the Y direction relative to the gate electrode GT is connected to the ground interconnect VSS via a local interconnect LI, a via V1 and a buried power rail BPR (VSS). By this means, a transistor NFET52 that functions as a circuit can be formed. Also, the transistor NFET52 is connected to the well region PW (VSS) via n+ diffusion regions, so that parasitic bipolar action via the well region PW becomes possible. The transistor NFET52 is an example of a second transistor, and the gate electrode of the transistor NFET52 is an example of a second gate electrode.

The p-type p+ diffusion regions and the n-type well region NW (VDD) of the transistor PFET 62, connected to form a pn junction, constitute the diode D60. The p-type well region PW (VSS) and the n-type n+ diffusion regions of the transistor NFET52, connected to form a pn junction, constitute the diode D50.

By this means, a circuit is formed with the transistors PFET 62 and NFET52 and diodes D60 and D50 illustrated in FIG. 12. In other words, the diode D60 is formed as a parasitic diode of the transistor PFET 62, and the diode D50 is formed as a parasitic diode of transistor NFET53.

For example, although the transistors PFET 61 to PFET 63 and NFET51 to NFET53 are nanosheet transistors, they may instead be formed with the FinFET transistors illustrated in FIG. 5. The diode regions D60 and D50 may be arranged alternately, and repeatedly, in the X direction. Also, the structure illustrated in FIG. 6 or FIG. 8 may be applied instead of the structure illustrated in FIG. 13.

Furthermore, in the event the transistor PFET 62 is a nanosheet transistor, the p+ diffusion regions of the transistor PFET 62 and the well region NW (VDD) may be insulated by an STI layer or the like. Also, when the diode D20 of FIG. 12 is formed using a nanosheet transistor as in FIG. 2, and the p+ diffusion regions and the well region NW (VDD) illustrated in FIG. 3 may be insulated by an STI layer or the like. By this means, the diodes D60 and D20 shown by broken lines in FIG. 12 are no longer present, so that the above-described control for preventing or substantially preventing through current is no longer necessary.

As described above, this embodiment can bring about the same effects and advantages as those of the first embodiment. For example, in a fail-safe IO buffer FSBUF, it is possible to prevent or substantially prevent a parasitic bipolar transistor from being formed between the well regions NW (VDD) and PW (VSS) of the diode regions D60 and D50 that are formed next to each other.

By this means, the gap between the diode regions D60 and D50 can be narrowed, so that the chip size of the semiconductor device SEM3 can be made smaller. In other words, even when the diodes D60 and D50 are formed as parasitic diodes of the transistors PFET 62 and NFET52, it is still possible to narrow the gap between the diode regions D60 and D50, so that the chip size of the semiconductor device SEM3 can be made smaller.

Although embodiments of the present invention have been described above, the details of the embodiments described herein by no means limit the present invention, can be changed in a variety of ways within the scope of the present invention, and can be determined as appropriate depending on the mode of implementation.

1. A semiconductor device comprising:
a substrate;
a first impurity region and a second impurity region formed on the substrate, the first and second impurity regions having first and second types of conductivity, respectively, and spaced apart in a first direction in plan view;
a third impurity region formed in contact with the first impurity region on the substrate and having the second type of conductivity;
a fourth impurity region formed in contact with the second impurity region on the substrate and having the first type of conductivity;
a first interconnect formed in the substrate, on a side of the third impurity region facing the fourth impurity region in plan view, the first interconnect extending in a second direction that is different from the first direction; and
a second interconnect formed in the substrate, on a side of the fourth impurity region facing the third impurity region in plan view, the second interconnect extending in the second direction.

2. The semiconductor device according to claim 1, further comprising:
a fifth impurity region formed on the third impurity region, spaced apart from the first impurity region in the second direction, and having the second type of conductivity; and
a sixth impurity region formed on the fourth impurity region, spaced apart from the second impurity region in the second direction, and having the first type of conductivity.

3. The semiconductor device according to claim 1, further comprising:
a third interconnect formed in the substrate, on a side of the third impurity region opposite from the first interconnect in plan view, the third interconnect extending in the second direction; and
a fourth interconnect formed in the substrate, on a side of the fourth impurity region opposite from the second interconnect in plan view, the fourth interconnect extending in the second direction.

4. The semiconductor device according to claim 3, further comprising:
a fifth impurity region formed on the third impurity region, spaced apart from the first impurity region in the second direction, and having the second type of conductivity; and
a sixth impurity region formed on the fourth impurity region, spaced apart from the second impurity region in the second direction, and having the first type of conductivity,
wherein the first impurity region and the second region to impurity are connected a signal interconnect,
wherein the third impurity region and the fifth impurity region are connected to one of a first power-supply interconnect or a second power-supply interconnect having respective voltages,
wherein the fourth impurity region and the sixth impurity region are connected to the other one of the first power-supply interconnect or the second power-supply interconnect,
wherein the first interconnect is connected to one of the first power-supply interconnect or the signal interconnect,
wherein the third interconnect is connected to the other one of the first power-supply interconnect or the signal interconnect,
wherein the second interconnect is connected to one of the second power-supply interconnect or the signal interconnect, and
wherein the fourth interconnect is connected to the other one of the second power-supply interconnect or the signal interconnect.

5. The semiconductor device according to claim 3, further comprising:
a fifth impurity region formed on the third impurity region, spaced apart from the first impurity region in the second direction, and having the second type of conductivity; and
a sixth impurity region formed on the fourth impurity region, spaced apart from the second impurity region in the second direction, and having the first type of conductivity,
wherein the first impurity region and the second impurity region are connected to one of a power-supply interconnect of a first power-supply domain or a power-supply interconnect of a second power-supply domain,
wherein the fifth impurity region and the sixth impurity region are connected to the other one of the power-supply interconnect of the first power-supply domain or the power-supply interconnect of the second power-supply domain,
wherein the first interconnect is connected to one of the power-supply interconnect of the first power-supply domain or the power-supply interconnect of the second power-supply domain,
wherein the third interconnect is connected to the other one of the power-supply interconnect of the first power-supply domain or the power-supply interconnect of the second power-supply domain,
wherein the second interconnect is connected to one of the power-supply interconnect of the first power-supply domain or the power-supply interconnect of the second power-supply domain, and
wherein the fourth interconnect is connected to the other one of the power-supply interconnect of the first power-supply domain or the power-supply interconnect of the second power-supply domain.

6. The semiconductor device according to claim 1, further comprising:
a first gate electrode arranged on the third impurity region;
a second gate electrode arranged on the fourth impurity region;
a first transistor including:
the first gate electrode; and
the first impurity region arranged on both sides of the first gate electrode in plan view; and
a second transistor including:
the second gate electrode; and
the second impurity region arranged on both sides of the second gate electrode in plan view.

7. The semiconductor device according to claim 6, further comprising:
a third interconnect formed in the substrate, on a side of the third impurity region opposite from the first interconnect in plan view, the third interconnect extending in the second direction; and
a fourth interconnect formed in the substrate, on a side of the fourth impurity region opposite from the second interconnect in plan view, the fourth interconnect extending in the second direction,
wherein the first impurity region arranged on one side of the first gate electrode is connected to one of a first power-supply interconnect or a signal interconnect,
wherein the first impurity region arranged on the other side of the first gate electrode is connected to the other one of the first power-supply interconnect or the signal interconnect,
wherein the second impurity region arranged on one side of the second gate electrode is connected to one of the second power-supply interconnect or the signal interconnect, and
wherein the second impurity region arranged on the other side of the second gate electrode is connected to the other one of the second power-supply interconnect or the signal interconnect.

8. The semiconductor device according to claim 7,
wherein the first interconnect is connected to one of the first power-supply interconnect or the signal interconnect,
wherein the third interconnect is connected to the other one of the first power-supply interconnect or the signal interconnect,
wherein the second interconnect is connected to one of the second power-supply interconnect or the signal interconnect, and
wherein the fourth interconnect is connected to the other one of the second power-supply interconnect or the signal interconnect.

9. The semiconductor device according to claim 6, wherein the first transistor and the second transistor are nanosheet transistors.

10. The semiconductor device according to claim 6, wherein the first transistor and the second transistor are FinFET transistors.
